(19) United States
(12) Patent Application Publication
(10) Pub. No.: US 2004/0222519 A1
(43) Pub. Date: Nov. 11, 2004

(54) Semiconductor device, electronic device, electronic apparatus, method of manufacturing semiconductor device, and method of manufacturing electronic device

(76) Inventor: Akiyoshi Aoyagi, Atsugi-shi (JP)

Correspondence Address: HARNESS, DICKEY & PIERCE, P.L.C., P.O. BOX 828, BLOOMFIELD HILLS, MI, 48303, US

(21) Appl. No.: 10/801,949

(22) Filed: Mar. 16, 2004

(30) Foreign Application Priority Data
Mar. 18, 2003 (JP) 2003-074218

(51) Int. Cl. H01L 23/48

(52) U.S. Cl. 257/734

(57) ABSTRACT

A method and device are provided to realize a structure in which different kinds of chips are three-dimensionally mounted while suppressing the deterioration of the connection reliability. A semiconductor package PK12 in which a semiconductor chip 13 is sealed with a sealing resin 17 is stacked on a semicoductor package PK11 in which a semiconductor chip 3 is mounted on a carrier substrate 1 by anisotropic conductive film (ACF) bonding. The range in which the semiconductor chip 13 is sealed with a sealing resin 17 is set so as to cover the semiconductor chip 13 and to be attached to the region for arranging the protruding electrodes 16 on the side of the surface on which the semiconductor chip 13 is mounted.

### RELATED APPLICATIONS

The present applicant claims priority to Japanese Patent Application No. 2003-074218 filed Mar. 18, 2003 which is hereby expressly incorporated by reference herein in its entirety.

### BACKGROUND

1. Technical Field of the Invention

The present invention relates to a semiconductor device, an electronic device, an electronic apparatus, a method of manufacturing a semiconductor device, and a method of manufacturing an electronic device which are suitable for application to, in particular, a stacked structure of semiconductor packages.

2. Description of the Related Art

In a conventional semiconductor device, in order to save space when semiconductor chips are mounted, for example, as disclosed in Japanese Unexamined Patent Application Publication No. 10-284683, a method of three-dimensionally mounting semiconductor chips on a carrier substrate is used.

However, according to the method of three-dimensionally mounting the semiconductor chips on the carrier substrate, warpage of the carrier substrate occurs, thereby deteriorating the connection reliability between the semiconductor chips when the semiconductor chips are three-dimensionally mounted. Therefore, it is difficult to stack different kinds of chips.

Accordingly, an object of the present invention is to provide a semiconductor device, an electronic device, an electronic apparatus, a method of manufacturing a semiconductor device, and a method of manufacturing an electronic device which are capable of realizing a structure in which different kinds of chips can be three-dimensionally mounted while suppressing the deterioration of the connection reliability.

### SUMMARY

In order to achieve the above object, according to one aspect of the present invention, there is provided a semiconductor device, comprising: a first carrier substrate; a first semiconductor chip mounted on the first carrier substrate; a second carrier substrate; a second semiconductor chip mounted on the second carrier substrate; protruding electrodes for connecting the second carrier substrate to the first carrier substrate so that the second carrier substrate is held above the first semiconductor chip; and a sealant for sealing the second semiconductor chip so as to include a region in which the protruding electrodes are arranged.

According to the above structure, it is possible to reinforce the region for arranging the protruding electrodes with the sealant for sealing the second semiconductor chips. Therefore, it is possible to reduce the warpage of the carrier substrate on which the second semiconductor chip are mounted while suppressing an increase in the height when the second carrier substrate is stacked on the first carrier substrate.

For this reason, it is possible to save space when the semiconductor chips are mounted while suppressing the deterioration of the connection reliability between the first carrier substrate and the second carrier substrate.

Further, in a semiconductor device according to one aspect of the present invention, the second carrier substrate is fixed to the first carrier substrate so as to be mounted on the first semiconductor chip.

According to the above structure, it is possible to overlap the first semiconductor chip and the second semiconductor chip with each other. As a result, it is possible to reduce the mounting area when a plurality of semiconductor chips is mounted and thereby save space when the semiconductor chips are mounted.

Further, in a semiconductor device according to one aspect of the present invention, the sealant is a molded resin.

According to the above structure, it is possible to stack different kinds of packages including the second carrier substrate on the first carrier substrate and thereby realize a structure in which the semiconductor chips are three-dimensionally mounted even when the kinds of the semiconductor chips vary.

Further, in a semiconductor device according to one aspect of the present invention, the position of a sidewall of the sealant coincides with that of a sidewall of the second carrier substrate.

According to the above structure, it is possible to reinforce one entire surface of the second carrier substrate with a sealant for sealing the second semiconductor chip while preventing an increase in the height when the second carrier substrate is stacked on the first carrier substrate and to seal the second semiconductor chip without dividing the sealant into cells. As a result, it is possible to increase the mounting area of the second semiconductor chip mounted on the second carrier substrate.

Further, in a semiconductor device according to one aspect of the present invention, the first semiconductor chip is flip-chip mounted on the first carrier substrate.

According to the above structure, it is possible to mount the first semiconductor chip on the first carrier substrate without laying wires around the first semiconductor chip. As a result, it is possible to reduce the height of the protruding electrodes that hold the second carrier substrate on the first carrier substrate and thereby improve the connection reliability between the first carrier substrate and the second carrier substrate while saving space.

Further, in a semiconductor device according to one aspect of the present invention, a plurality of the first semiconductor chips is provided in parallel on the first carrier substrate.

According to the above structure, it is possible to overlap the second semiconductor chip and the plurality of first semiconductor chips with each other and thereby reduce the mounting area when the plurality of semiconductor chips is mounted. As a result, it is possible to save space when the semiconductor chips are mounted.

Further, in a semiconductor device according to one aspect of the present invention, the first semiconductor chip is connected to the first carrier substrate by pressure welding.

According to the above structure, it is possible to lower the temperature when the first semiconductor chip is connected to the first carrier substrate and thereby reduce warpage of the first carrier substrate when the first carrier substrate is actually used.

Further, in a semiconductor device according to one aspect of the present invention, at the same temperature, the elastic modulus of a semiconductor device including the first carrier substrate and the first semiconductor chip mounted on the first carrier substrate is different from the elastic modulus of a semiconductor device including the second carrier substrate and the second semiconductor chip mounted on the second carrier substrate.

According to the above structure, it is possible to prevent warpage of one carrier substrate by the other carrier substrate and thereby improve the connection reliability between the first carrier substrate and the second carrier substrate.

Further, in a semiconductor device according to one aspect of the present invention, the first carrier substrate on which the first semiconductor chip is mounted is a flip-chip-mounted ball grid array, and the second carrier substrate on which the second semiconductor chip is mounted is a mold-sealed ball grid array or a chip size package.

According to the above structure, it is possible to stack different kinds of packages while suppressing an increase in the height of a structure in which the semiconductor chips are three-dimensionally mounted and thereby save space when the semiconductor chips are mounted even when the kinds of the semiconductor chips vary.

Further, according to one aspect of the present invention, there is provided a semiconductor device, comprising: a carrier substrate; a first semiconductor chip mounted on the carrier substrate; a second semiconductor chip mounted on the carrier substrate; protruding electrodes for connecting the second semiconductor chip to the carrier substrate so that the second semiconductor chip is held above the first semiconductor chip; and a sealant for sealing the second semiconductor chip so as to include a region in which the protruding electrodes are arranged.

According to the above structure, even when the kinds or the sizes of the semiconductor chips vary, it is possible to flip-chip mount the second semiconductor chip on the carrier substrate so that the first semiconductor chip is arranged on the second semiconductor chip without interposing the carrier substrates between the first semiconductor chip and the second semiconductor chip. It is also possible to reinforce the region for arranging the protruding electrodes with the sealant for sealing the second electronic chip.

For this reason, it is possible to reduce the warpage of the carrier substrate while suppressing an increase in the height when the semiconductor chips are stacked and thereby save space when the semiconductor chips are mounted while suppressing the deterioration of connection reliability of the three-dimensionally mounted semiconductor chips.

Further, in a semiconductor device according to one aspect of the present invention, the second semiconductor chip comprises a plurality of stacked semiconductor chips.

According to the above structure, it is possible to stack a plurality of second semiconductor chips of different kinds and sizes on the first semiconductor chip and thereby save space when the semiconductor chips are mounted, and it is possible to let the semiconductor chips have various functions.

Further, in a semiconductor device according to one aspect of the present invention, the second semiconductor chip comprises a plurality of semiconductor chips mounted in parallel on the second carrier substrate.

According to the above structure, it is possible to arrange the plurality of second semiconductor chips on the first semiconductor chips while preventing an increase in the height when the second semiconductor chips are stacked. As a result, it is possible to prevent the deterioration of the connection reliability when the semiconductor chips are three-dimensionally mounted and save space when the semiconductor chips are mounted.

Further, according to one aspect of the present invention, there is provided an electronic device, comprising: a first carrier substrate; a first electronic part mounted on the first carrier substrate; a second carrier substrate; a second electronic part mounted on the second carrier substrate; protruding electrodes connecting the second carrier substrate to the first carrier substrate so that the second carrier substrate is held above the first electronic part; and a sealant sealing the second electronic part so as to include a region in which the protruding electrodes are arranged.

According to the above structure, it is possible to reinforce the region for arranging the protruding electrodes with the sealant for sealing the second electronic part and thereby reduce warpage of the second carrier substrate on which the second electronic part is mounted while suppressing an increase in the height when the second carrier substrate is stacked on the first carrier substrate.

Further, according to one aspect of the present invention, there is provided an electronic apparatus, comprising: a first carrier substrate; a first semiconductor chip mounted on the first carrier substrate; a second carrier substrate; a second semiconductor chip mounted on the second carrier substrate; protruding electrodes for connecting the second carrier substrate to the first carrier substrate so that the second carrier substrate is held above the first semiconductor chip; a sealant for sealing the second semiconductor chip so as to include a region in which the protruding electrodes are arranged; and a mother substrate on which the first carrier substrate is mounted.

Therefore, it is possible to reinforce the region for arranging the protruding electrodes with the sealant for sealing the second semiconductor chip and thereby reduce warpage of the second carrier substrate on which the second semiconductor chip is mounted. As a result, it is possible to improve the connection reliability when the semiconductor chips are mounted.

Further, according to one aspect of the present invention, there is provided a method of manufacturing a semiconductor device, comprising the steps of: flip-chip mounting a first semiconductor chip on a first carrier substrate; mounting a second semiconductor chip on a second carrier substrate in which an arrangement region for arranging protruding electrodes is provided; sealing the second semiconductor chip with sealing resin so that the sealing resin is attached to the region for arranging the protruding electrodes; and connecting the second carrier substrate to the first carrier substrate via the protruding electrodes so that the second carrier substrate is held above the first semiconductor chip.

According to the above structure, it is possible to reinforce the region for arranging the protruding electrodes with the sealant for sealing the second semiconductor chip and thereby reduce warpage of the second carrier substrate. As a result, when the second carrier substrate is stacked on the first carrier substrate via the protruding electrodes, it is possible to reduce nonuniformity in the gap between the first carrier substrate and the second carrier substrate and thereby improve the connection reliability between the first carrier substrate and the second carrier substrate.

Further, in a method of manufacturing a semiconductor device according to one aspect of the present invention, the step of sealing the second semiconductor chip with the sealing resin comprises the steps of: integrally molding a plurality of the second semiconductor chips, which are mounted on the second carrier substrate, with the sealing resin; and cutting the second carrier substrate molded with the sealing resin into pieces so that each piece includes one of the second semiconductor chips.

According to the above structure, it is possible to seal the second semiconductor chips with sealing resin without dividing the sealing resin into cells in each second semiconductor chip and to reinforce one entire surface of the second carrier substrate with the sealing resin.

For this reason, even when the kinds or the sizes of the second semiconductor chips vary, it is possible to share a mold when the second semiconductor chips are molded and thereby to make the sealing resin process efficient. Also, since space for dividing the sealing resin into cells is unnecessary, it is possible to increase the mounting area of the second semiconductor chips mounted on the second carrier substrate.

Further, according to one aspect of the present invention, there is provided a method of manufacturing an electronic device, comprising the steps of: mounting a first electronic part on a first carrier substrate; mounting a second electronic part on a second carrier substrate in which an arrangement region for arranging protruding electrodes is provided; sealing the second electronic part with a sealing resin so that the sealing resin is attached to the region for arranging the protruding electrodes; and connecting the second carrier substrate to the first carrier substrate via protruding electrodes so that the second carrier substrate is held above the first electronic part.

According to the above structure, it is possible to reinforce the region for arranging the protruding electrodes with sealing resin for sealing the second electronic part and thereby reduce warpage of the second carrier substrate.

For this reason, it is possible to reduce nonuniformity in the gap between the first carrier substrate and the second carrier substrate when the second carrier substrate is stacked on the first carrier substrate via the protruding electrodes. It is also possible to improve the connection reliability between the first carrier substrate and the second carrier substrate.

### BRIEF DESCRIPTION OF THE DRAWINGS

FIG. 1 is a sectional view illustrating the structure of a semiconductor device according to a first embodiment.

FIG. 2 is a sectional view illustrating the structure of a semiconductor device according to a second embodiment.

FIG. 3 is a sectional view illustrating a semiconductor device according to a third embodiment.

FIGS. 4A-D are sectional views illustrating a method of manufacturing a semiconductor device according to a fourth embodiment.

FIGS. 5A-C are sectional views illustrating a method of manufacturing a semiconductor device according to a fifth embodiment.

FIG. 6 is a sectional view illustrating the structure of a semiconductor device according to a sixth embodiment.

FIG. 7 is a sectional view illustrating the structure of a semiconductor device according to a seventh embodiment.

FIG. 8 is a sectional view illustrating the structure of a semiconductor device according to an eighth embodiment.

### DETAILED DESCRIPTION

A semiconductor device and an electronic device and a method of manufacturing the same according to the embodiments of the present invention will now be described with reference to the drawings.

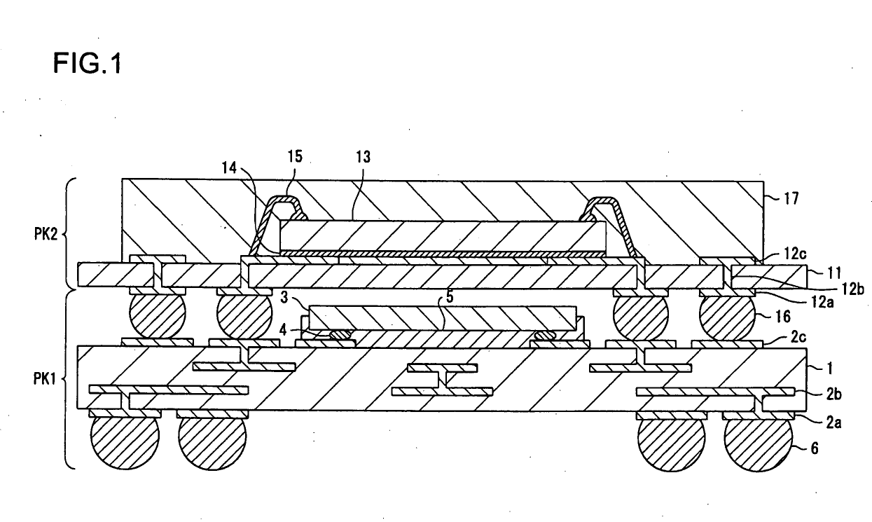

FIG. 1 is a sectional view illustrating the structure of a semiconductor device according to a first embodiment of the present invention. According to the first embodiment, a semiconductor package PK2 in which a semiconductor chip (or a semiconductor die) 13 is sealed with a sealing resin 17 is stacked on a semiconductor package PK1 in which a semiconductor chip (or a semiconductor die) 3 is mounted on a carrier substrate by anisotropic conductive film (ACF) bonding.

In FIG. 1, a carrier substrate 1 is provided in the semiconductor package PK1. Lands 2a and 2c are respectively formed on both faces of the carrier substrate 1. Internal wiring lines 2b are formed in the carrier substrate 1. The semiconductor chip 3 is flip-chip mounted on the carrier substrate 1. Protruding electrodes 4 for flip-chip mounting the semiconductor chip 3 are provided on the semiconductor chip 3. The protruding electrodes 4 provided on the semiconductor chip 3 are bonded to the lands 2c via an anisotropic conductive film 5 by ACF bonding. Further, protruding electrodes 6 for mounting the carrier substrate 1 on a mother substrate are provided on the lands 2a on the reverse face of the carrier substrate 1.

On the other hand, a carrier substrate 11 is provided in a semiconductor package PK2. Lands 12a and 12c are respectively formed on both faces of the carrier substrate 11. Internal wiring lines 12b are formed in the carrier substrate 11. The semiconductor chip 13 is mounted face up on the carrier substrate 11 via an adhesion layer 14. The semiconductor chip 13 is wire-bonded to the lands 12c via a conductive wire 15.

Further, protruding electrodes 16 for mounting the carrier substrate 11 on the carrier substrate 1 are provided on the lands 12a on the reverse face of the carrier substrate 11 so that the carrier substrate 11 is held above the semiconductor chip 3. The protruding electrodes 16 are arranged so as to avoid the region on which the semiconductor chip 3 is mounted. It is possible to arrange the protruding electrodes 16, for example, around a peripheral region of the reverse face of the carrier substrate 11. The carrier substrate 11 is mounted on the carrier substrate 1 by bonding the protruding electrodes 16 to the lands 2c provided on the carrier substrate 1. When the carrier substrate 11 is mounted on the carrier substrate 1, the reverse face of the carrier substrate 11 may be close to or separated (spaced apart) from the semiconductor chip 3.

Further, the semiconductor chip 13 mounted on the carrier substrate 11 is sealed with a sealing resin 17. The range in which the semiconductor chip 13 is sealed with the sealing resin 17 is set so as to cover the semiconductor chip 13 and to be attached to the region for arranging the protruding electrodes 16 on the side of the surface on which the semiconductor chip 13 is mounted. Moreover, the semiconductor chip 13 is sealed with the sealing resin 17 by molding the semiconductor chip 13 using thermosetting resin such as epoxy resin.

Therefore, it is possible to improve the rigidity of the region for arranging the protruding electrodes 16 with the sealing resin 17 for sealing the semiconductor chip 13 and thereby reduce warpage of the carrier substrate 11 on which the semiconductor chip 13 is mounted while suppressing an increase in the height of the semiconductor package PK2.

For this reason, when the semiconductor package PK2 is stacked on the semiconductor package PK1, it is possible to reduce nonuniformity in the gap between the carrier substrate 1 and the carrier substrate 11 and thereby save space when the semiconductor chips 3 and 13 are mounted while suppressing the deterioration of the connection reliability, which is caused by the protruding electrodes 16.

It is also possible to stack the different kinds of packages PK1 and PK2 or the different kinds of semiconductor chips 3 and 13 by stacking the mold sealed semiconductor package PK2 on the flip-chip mounted semiconductor package PK1. For this reason, it is possible to realize various functions while reducing the mounting area by using a structure in which the semiconductor packages PK1 and PK2 are stacked.

For example, a dual-sided substrate, a multi-layer wiring line substrate, a built-up substrate, a tape substrate or a film substrate may be used as the carrier substrates 1 and 11. The carrier substrates 1 and 11 may be made of, for example, polyimide resin, glass epoxy resin, BT resin, a composite of aramide and epoxy, and ceramic. For example, an Au bump, a Cu bump and a Ni bump coated with solder, and solder balls may be used as the protruding electrode 4, 6 and 16. For example, an Au wire or an Al wire may be used as the conductive wire 15. The method of providing the protruding electrodes 16 on the lands 12a of the carrier substrate 11 in order to mount the carrier substrate 11 on the carrier substrate 1 is described in the above-mentioned embodiment. However, the protruding electrodes 16 may be provided on the lands 2c of the carrier substrate 1.

Further, a method of mounting the semiconductor chip 3 on the carrier substrate 1 by ACF bonding is described in the above-mentioned embodiment. However, for example, pressure welding such as nonconductive film (NCF) bonding, anisotropic conductive paste (ACP) bonding, or nonconductive paste (NCP) bonding may be used. Metal joining such as soldering or alloy joining may be used. Further, the method of mounting the semiconductor chip 13 on the carrier substrate 11 using wire bonding is described. However, the semiconductor chip 13 may be flip-chip mounted on the carrier substrate 11. Furthermore, a method of mounting only one semiconductor chip 3 on the carrier substrate 1 is described in the above-mentioned embodiment. However, a plurality of semiconductor chips may also be mounted on the carrier substrate 1. Further, a resin may be implanted into the gap between the carrier substrate 1 and the carrier substrate 11, if necessary.

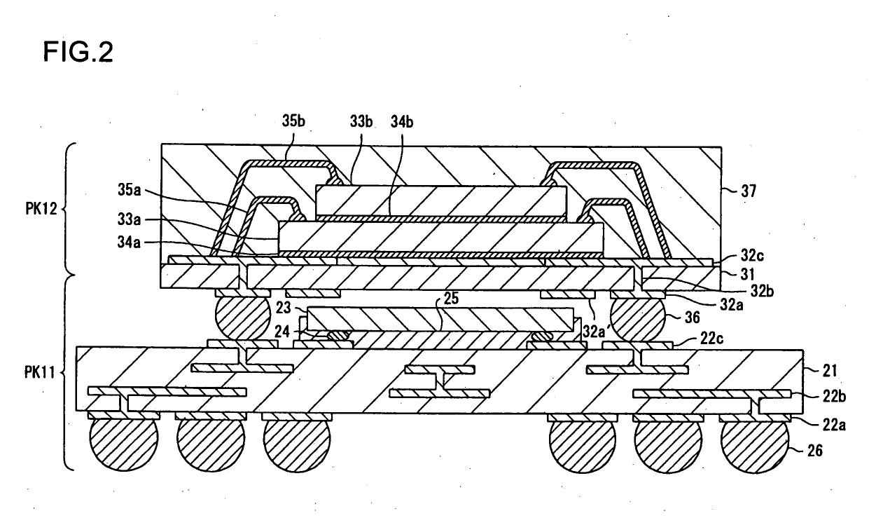

FIG. 2 is a sectional view illustrating the structure of a semiconductor device according to a second embodiment of the present invention. According to the second embodiment, a semiconductor package PK12 in which stacked semiconductor chips 33a and 33b are wire-bonded is stacked on a semiconductor package PK11 in which a semiconductor chip 23 is mounted by ACF bonding.

In FIG. 2, a carrier substrate 21 is provided in the semiconductor package PK11. Lands 22a and 22c are respectively formed on both faces of the carrier substrate 21. Internal wiring lines 22b are formed in the carrier substrate 21. The semiconductor chip 23 is flip-chip mounted on the carrier substrate 21. Protruding electrodes 24 for flip-chip mounting the semiconductor chip 23 are provided on the semiconductor chip 23. The protruding electrodes 24 provided on the semiconductor chip 23 are bonded to the lands 22c via an anisotropic conductive film 25 by ACF bonding. Further, protruding electrodes 26 for mounting the carrier substrate 21 on a mother substrate are provided on the lands 22a on the reverse face of the carrier substrate 21.

Since the semiconductor chip 23 is mounted on the carrier substrate 21 by ACF bonding, space for performing wire bonding or mold sealing is unnecessary. Therefore, it is possible to save space when the semiconductor chips are three-dimensionally mounted and to lower the temperature when the semiconductor chip 23 is bonded to the carrier substrate 21. As a result, it is possible to reduce warpage of the carrier substrate 21 when the carrier substrate 21 is actually used.

On the other hand, a carrier substrate 31 is provided in the semiconductor package PK12. Lands 32a and 32c are respectively formed on both faces of the carrier substrate 31. Internal wiring lines 32b are formed in the carrier substrate 31. A semiconductor chip 33a is mounted face up on the carrier substrate 31 via an adhesion layer 34a. The semiconductor chip 33a is wire-bonded to the lands 32c via conductive wires 35a. Furthermore, a semiconductor chip 33b is mounted face up on the semiconductor chip 33a so as to avoid the conductive wires 35a. The semiconductor chip 33b is fixed to the semiconductor chip 33a via an adhesion layer 34b and is wire-bonded to the lands 32c via conductive wires 35b.

Further, protruding electrodes 36 for mounting the carrier substrate 31 on the carrier substrate 21 are provided on the lands 32a on the reverse face of the carrier substrate 31 so that the carrier substrate 31 is held above the semiconductor chip 23. The protruding electrodes 36 are arranged so as to avoid the region on which the semiconductor chip 23 is mounted. It is possible to arrange the protruding electrodes 36, for example, around a peripheral region of the reverse face of the carrier substrate 31. The carrier substrate 31 is mounted on the carrier substrate 21 by bonding the protruding electrodes 36 to the lands 22c provided on the carrier substrate 21. When the carrier substrate 31 is mounted on the carrier substrate 21, the reverse face of the carrier substrate 31 may be close to or separated from the semiconductor chip 23.

For example, solder balls may be used as the protruding electrodes 26 and 36. Therefore, it is possible to stack the different kinds of packages PK11 and PK12 on each other by using regular BGA and thereby apply the manufacturing line to other fields.

Further, a sealing resin 37 is provided on one entire surface of the carrier substrate 31 on which semiconductor chips 33a and 33b are mounted. The semiconductor chips 33a and 33b are sealed with the sealing resin 37. When the semiconductor chips 33a and 33b are sealed with the sealing resin 37, the semiconductor chips 33a and 33b may be molded using thermosetting resin such as epoxy resin.

Therefore, it is possible to seal the semiconductor chips 33a and 33b while reinforcing the region for arranging the protruding electrodes 36 with the sealing resin 37 and thereby improve the rigidity of the region for arranging the protruding electrodes 36 while suppressing an increase in the height of the semiconductor package PK12.

For this reason, it is possible to reduce warpage of the carrier substrate 31 on which the semiconductor chips 33a and 33b are mounted and thereby improve the connection reliability by the protruding electrodes 36 and to three-dimensionally mount the stacked semiconductor chips 33a and 33b on the semiconductor chip 23. As a result, it is possible to save space when the semiconductor chips 23, 33a, and 33b are mounted.

Further, the sealing resin 37 is formed on one entire surface of the carrier substrate 31 on which the semiconductor chips 33a and 33b are mounted. Therefore, even when the various kinds of semiconductor chips 33a and 33b are mounted on the carrier substrate 31, it is possible to share a mold when the sealing resin 37 is molded and thereby make the sealing resin process efficient. Also, since space for dividing the sealing resin 37 into cells is unnecessary, it is possible to increase the mounting area of the semiconductor chips 33a and 33b mounted on the carrier substrate 31.

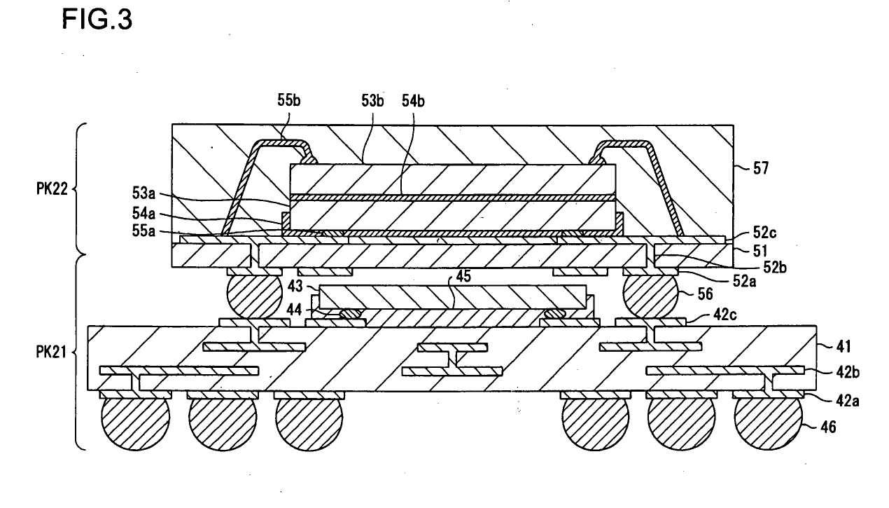

FIG. 3 is a sectional view illustrating the structure of a semiconductor device according to a third embodiment of the present invention. According to the third embodiment, a semiconductor package PK22 in which stacked semiconductor chips 53a and 53b are flip-chip mounted and wire-bonded, respectively, is stacked on a semiconductor package PK21 in which a semiconductor chip 43 is mounted by ACF bonding.

In FIG. 3, a carrier substrate 41 is provided in the semiconductor package PK21. Lands 42a and 42c are formed on both faces of the carrier substrate 41. Internal wiring lines 42b are formed in the carrier substrate 41. The semiconductor chip 43 is flip-chip mounted on the carrier substrate 41. Protruding electrodes 44 for flip-chip mounting the semiconductor chip 43 are provided on the semiconductor chip 43. The protruding electrodes 44 provided on the semiconductor chip 43 are bonded to the lands 42c via an anisotropic conductive film 45 by ACF bonding. Protruding electrodes 46 for mounting the carrier substrate 41 on a mother substrate are provided on the lands 42a on the reverse face of the carrier substrate 41.

Since the semiconductor chip 43 is mounted on the carrier substrate 41 by ACF bonding, a space for performing wire bonding or mold sealing is unnecessary. Therefore, it is possible to save space when the semiconductor chip 43 is three-dimensionally mounted and to lower the temperature when the semiconductor chip 43 is bonded to the carrier substrate 41. As a result, it is possible to reduce warpage of the carrier substrate 41 when the carrier substrate 41 is actually used.

On the other hand, a carrier substrate 51 is provided in the semiconductor package PK22. Lands 52a and 52c are respectively formed on both faces of the carrier substrate 51. Internal wiring lines 52b are formed in the carrier substrate 5i. A semiconductor chip 53a is flip-chip mounted on the carrier substrate 51. Protruding electrodes 55a for flip-chip mounting the semiconductor chip 53a are provided on the semiconductor chip 53a. The protruding electrodes 55a provided on the semiconductor chip 53a are bonded to the lands 52a via an anisotropic conductive film 54a by ACF bonding. Furthermore, a semiconductor chip 53b is mounted face up on the semiconductor chip 53a. The semiconductor chip 53b is fixed to the semiconductor chip 53a via an adhesion layer 54b and is wire-bonded to the lands 52c via conductive wires 55b.

It is possible to stack the semiconductor chip 53b of a size equal to or larger than the semiconductor chip 53a on the semiconductor chip 53a by mounting the semiconductor chip 53b face up on the face-down mounted semiconductor chip 53a without interposing a carrier substrate and thereby reduce the mounting area.

Further, protruding electrodes 56 for mounting the carrier substrate 51 on the carrier substrate 41 are provided on the lands 52a on the reverse face of the carrier substrate 51 so that the carrier substrate 51 is held above the semiconductor chip 43. The protruding electrodes 56 are arranged so as to avoid the region on which the semiconductor chip 43 is mounted. It is possible to arrange the protruding electrodes 56, for example, around a peripheral region of the reverse face of the carrier substrate 51. Further, the carrier substrate 51 is mounted on the carrier substrate 41 by bonding the protruding electrodes 56 to the lands 42c provided on the carrier substrate 41. When the carrier substrate 51 is mounted on the carrier substrate 41, the reverse face of the carrier substrate 51 may be close to or separated from the semiconductor chip 43.

For example, solder balls may be used as the protruding electrodes 46 and 56. Therefore, it is possible to stack the different kinds of packages PK21 and PK22 on each other by using regular BGA and thereby apply the manufacturing line to other fields.

Further, a sealing resin 57 is provided on one entire surface of the carrier substrate 51 on which semiconductor chips 53a and 53b are mounted. Moreover, the semiconductor chips 53a and 53b are sealed with the sealing resin 57. When the semiconductor chips 53a and 53b are sealed with the sealing resin 57, the semiconductor chips 53a and 53b may be molded using thermosetting resin such as epoxy resin.

Therefore, it is possible to seal the semiconductor chips 53a and 53b while reinforcing the region for arranging the protruding electrodes 56 with the sealing resin 57 and thereby improve the rigidity of the region for arranging the protruding electrodes 56 while suppressing an increase in the height of the semiconductor package PK22.

For this reason, it is possible to reduce warpage of the carrier substrate 51 on which the semiconductor chips 53a and 53b are mounted and thereby improve the connection reliability by the protruding electrodes 56 and to three-dimensionally mount the stacked semiconductor chips 53a and 53b on the semiconductor chip 43. As a result, it is possible to save space when the semiconductor chips 43, 53a, and 53b are mounted.

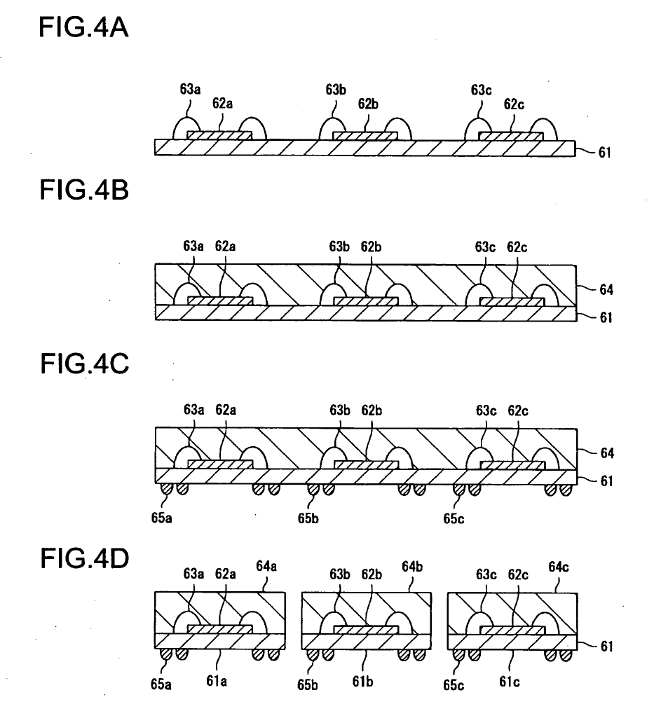

FIG. 4 is a sectional view illustrating a method of manufacturing a semiconductor device according to a fourth embodiment of the present invention. According to the forth embodiment, after a plurality of semiconductor chips 62a to 62c are integrally molded with a sealing resin 64, a carrier substrate 61 and the sealing resin 64 are cut into pieces so that each piece includes one of the semiconductor chips 62a to 62c. Therefore, sealing resins 64a to 64c are respectively formed on one entire surface of carrier substrates 61a to 61c on which the semiconductor chips 62a to 62c are respectively mounted.

In FIG. 4(a), a mounting region on which the plurality of semiconductor chips 62a to 62c is mounted is provided in the carrier substrate 61. The plurality of semiconductor chips 62a to 62c is mounted on the carrier substrate 61 and is wire-bonded to the carrier substrate 61 via conductive wires 63a to 63c. Other than the method of wire-bonding the semiconductor chips 62a to 62c to the carrier substrate 61, the semiconductor chips 62a to 62c may be flip-chip mounted on the carrier substrate 61, and a structure in which the semiconductor chips 62a to 62c are stacked may be mounted on the carrier substrate 61.

Next, as illustrated in FIG. 4(b), the plurality of semiconductor chips 62a to 62c mounted on the carrier substrate 61 are integrally molded with a sealing resin 64. Even when the various kinds of semiconductor chips 62a to 62c are mounted on the carrier substrate 61 by integrally molding the plurality of semiconductor chips 62a to 62c with the sealing resin 64, it is possible to share a mold when the semiconductor chips 62a to 62c are molded and thereby make the sealing resin process efficient. Also, since space for dividing the sealing resin 64 into cells is unnecessary, it is possible to increase the mounting area of the semiconductor chips 62a to 62c mounted on the carrier substrate 61.

Next, as illustrated in FIG. 4(c), protruding electrodes 65a to 65c made of solder balls are respectively formed on the reverse faces of the carrier substrates 61a to 61c. As illustrated in FIG. 4(d), by cutting the carrier substrate 61 and the sealing resin 64 so that each cut piece includes one of the semiconductor chips 62a to 62c, the carrier substrate 61 is divided into the carrier substrates 61a to 61c on which the semiconductor chips 62a to 62c are respectively sealed with the sealing resins 64a to 64c. After cutting the carrier substrate 61 and the sealing resin 64 into pieces so that each cut piece includes one of the semiconductor chips 62a to 62c, the protruding electrodes made of solder balls may be formed.

It is possible to respectively form the sealing resins 64a to 64c on one entire surface of the carrier substrates 61a to 61c on which the semiconductor chips 62a to 62c are mounted by integrally cutting the carrier substrate 61 and the sealing resin 64. For this reason, it is possible to improve the rigidity of the region in which the protruding electrodes 65a to 65c are arranged while preventing the manufacturing process from becoming complicated and thereby reduce warpage of the carrier substrates 61a to 61c.

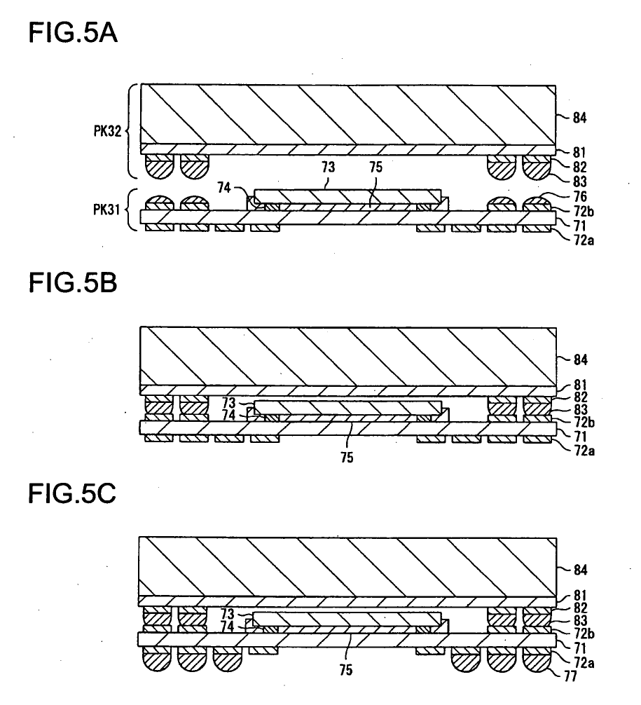

FIG. 5 is a sectional view illustrating a method of manufacturing a semiconductor device according to a fifth embodiment of the present invention. According to the fifth embodiment, a semiconductor package PK32 sealed with a sealing resin 84 is stacked on a semiconductor package PK31 on which a semiconductor chip 73 is mounted by ACF bonding.

In FIG. 5(a), a carrier substrate 71 is provided in the semiconductor package PK31. Lands 72a and 72b are respectively formed on both faces of the carrier substrate 71. The semiconductor chip 73 is flip-chip mounted on the carrier substrate 71. Protruding electrodes 74 for flip-chip mounting the semiconductor chip 73 are provided on the semiconductor chip 73. The protruding electrodes 74 provided on the semiconductor chip 73 are bonded to the lands 72b via an anisotropic conductive film 75 by ACF bonding.

On the other hand, a carrier substrate 81 is provided in a semiconductor package PK32. Lands 82 are respectively formed on the reverse face of the carrier substrate 81. Protruding electrodes 83 made of solder balls are provided on the lands 82. Further, a semiconductor chip is mounted on the carrier substrate 81. One entire surface of the carrier substrate 81 on which the semiconductor chip is mounted is sealed with a sealing resin 84. A wire-bonded semiconductor chip may be mounted on the carrier substrate 81. A semiconductor chip may be flip-chip mounted on the carrier substrate 81. A structure in which semiconductor chips are stacked may be mounted on the carrier substrate 81.

When the semiconductor package PK32 is stacked on the semiconductor package PK31, flux 76 is provided on the lands 72b of the carrier substrate 71. Soldering paste instead of flux 76 may be provided on the lands 72b of the carrier substrate 71.

Next, as illustrated in FIG. 5(b), protruding electrodes 83 are bonded to the lands 72b by mounting the semiconductor package PK32 on the semiconductor package PK31 and performing a reflow process.

Next, as illustrated in FIG. 5(c), protruding electrodes 77 for mounting the carrier substrate 71 on the lands 72a on the reverse face of the carrier substrate 71 on a mother substrate are formed.

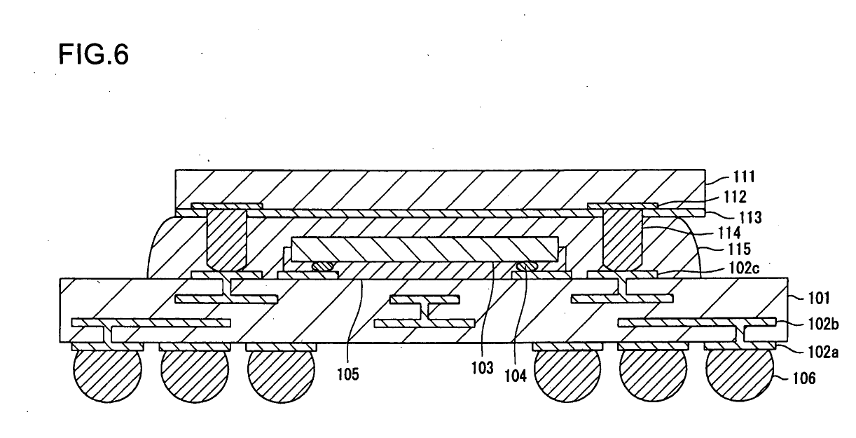

FIG. 6 is a sectional view illustrating the structure of a semiconductor device according to a sixth embodiment of the present invention. According to the sixth embodiment, semiconductor chips 103 and 111 are three-dimensionally mounted by flip-chip mounting the semiconductor chips 103 and 111 on a carrier substrate 101.

In FIG. 6, lands 102a and 102c are respectively formed on both faces of the carrier substrate 101. Internal wiring lines 102b are formed in the carrier substrate 101. The semiconductor chip 103 is flip-chip mounted on the carrier substrate 101. Protruding electrodes 104 for flip-chip mounting the semiconductor chip 103 are provided on the semiconductor chip 103. The protruding electrodes 104 provided on the semiconductor chip 103 are bonded to the lands 102c via an anisotropic conductive film 105 by ACF bonding. When the semiconductor chip 103 is mounted on the carrier substrate 101, alternatives to ACF bonding may be used; for example, other pressure welding such as NCF bonding may be used. Metal joining such as soldering and alloy joining may be used. Further, protruding electrodes 106 for mounting the carrier substrate 101 on a mother substrate are provided on the lands 102a provided on the reverse face of the carrier substrate 101.

On the other hand, electrode pads 112 are provided on the semiconductor chip 111. An insulating film 113 is provided so as to expose the electrode pads 112. Protruding electrodes 114 for flip-chip mounting the semiconductor chip 111 so that the semiconductor chip 111 is provided on the semiconductor chip 103 are provided on the electrode pads 112.

The protruding electrodes 114 are arranged so as to avoid the region on which the semiconductor chip 103 is mounted, for example, around a peripheral region of the semiconductor chip 111. The protruding electrodes 114 are bonded to the lands 102c provided on the carrier substrate 101, the semiconductor chip 111 mounted on the carrier substrate 101 is sealed with a sealing resin 115, and the semiconductor chip 111 is flip-chip mounted on the carrier substrate 101.

Therefore, even when the kinds or the sizes of the semiconductor chips 103 and 111 vary, it is possible to flip-chip mount the semiconductor chip 111 on the semiconductor chip 103 without interposing a carrier substrate between the semiconductor chip 103 and the semiconductor chip 111 and thereby reinforce the region for arranging the protruding electrodes 114 with the sealing resin 115 for sealing the semiconductor chip 111. As a result, it is possible to reduce warpage of the carrier substrate 101 while suppressing an increase in the height when the semiconductor chips 103 and 111 are stacked and thereby save space when the semiconductor chips 103 and 111 are mounted while suppressing the deterioration of the connection reliability when the semiconductor chips 103 and 111 are three-dimensionally mounted.

When the semiconductor chip 111 is mounted on the carrier substrate 101, the semiconductor chip 111 may be close to or separated from the semiconductor chip 103. When the semiconductor chip 111 is mounted on the carrier substrate 101, pressure welding such as ACF bonding and NCF bonding and metal joining such as soldering and alloy joining may be used. An Au bump, a Cu bump and a Ni bump coated with solder, and solder balls may be used as the protruding electrodes 104, 106, and 114. According to the above-mentioned embodiment, the method of flip-chip mounting the semiconductor chip 111 on one semiconductor chip 103 flip-chip mounted on the carrier substrate 101 is described. However, the semiconductor chip 111 may be flip-chip mounted on a plurality of semiconductor chips flip-chip mounted on the carrier substrate 101.

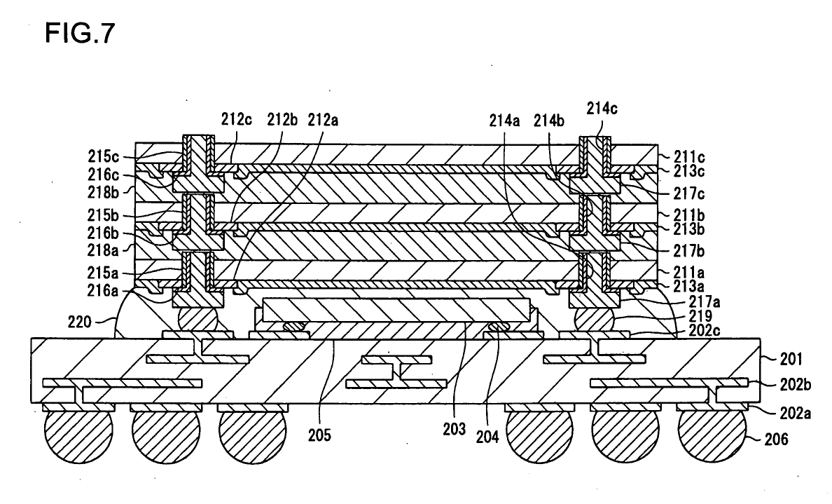

FIG. 7 is a sectional view illustrating the structure of a semiconductor device according to a seventh embodiment of the present invention. According to the seventh embodiment, a structure in which semiconductor chips 211a to 211c are stacked is three-dimensionally mounted on a carrier substrate 201 on which a semiconductor chip 203 is flip-chip mounted.

In FIG. 7, lands 202a and 202c are respectively formed on both faces of the carrier substrate 201. Internal wiring lines 202b are formed in the carrier substrate 201. The semiconductor chip 203 is flip-chip mounted on the carrier substrate 201. Protruding electrodes 204 for flip-chip mounting the semiconductor chip 203 are provided on the semiconductor chip 203. The protruding electrodes 204 provided on the semiconductor chip 203 are bonded to the lands 202c via an anisotropic conductive film 205 by ACF bonding. When the semiconductor chip 203 is mounted on the carrier substrate 201, alternatives to ACF bonding may be used; for example, pressure welding such as NCF bonding may be used. Metal joining such as soldering and alloy joining may be used. Further, protruding electrodes 206 for mounting the carrier substrate 201 on a mother substrate are provided on the lands 202a on the reverse face of the carrier substrate 201.

On the other hand, electrode pads 212a to 212c are provided on the semiconductor chips 211a to 211c. Insulating films 213a to 213c are respectively provided on the semiconductor chips 211a to 211c so that the electrode pads 212a to 212c are exposed. Through holes 214a to 214c are respectively formed in the semiconductor chips 211a to 211c so as to correspond to the positions of the electrode pads 212a to 212c. Through electrodes 217a to 217c are respectively formed in the through holes 214a to 214c via insulating films 215a to 215c and conductive films 216a to 216c.

The semiconductor chips 211a to 211c in which the through electrodes 217a to 217c are formed are stacked via the through electrodes 217a to 217c. Resin 218a and 218b is implanted into gaps among the semiconductor chips 211a to 211c.

Protruding electrodes 219 for flip-chip mounting a structure in which semiconductor chips 211a to 211c are stacked so that the structure in which the semiconductor chips 211a to 211c are stacked is provided on the semiconductor chip 203 are provided on the through electrode 217a formed in the semiconductor chip 211a.

The protruding electrodes 219 are arranged so as to avoid a region on which the semiconductor chip 203 is mounted. The protruding electrodes 219 may be arranged, for example, in a peripheral region of the semiconductor chip 211a. The protruding electrodes 219 are bonded to the lands 202c provided on the carrier substrate 201. The face of the semiconductor chip 211a mounted on the carrier substrate 201 is sealed with a sealing resin 220 and the structure in which the semiconductor chips 211a to 211c are stacked is flip-chip mounted on the carrier substrate 201.

Therefore, it is possible to flip-chip mount the structure in which the semiconductor chips 211a to 211c are stacked on the semiconductor chip 203 without interposing a carrier substrate between the structure in which the semiconductor chips 211a to 211c are stacked and the semiconductor chip 203, and thereby stack the semiconductor chip 203 and the different kinds of semiconductor chips 211a to 211c while suppressing an increase in the height when the semiconductor chips 203 and 211a to 211c are stacked.

When stacked semiconductor chips 211a to 211c are mounted on the carrier substrate 201, pressure welding such as ACF bonding or NCF bonding may be used. Metal joining such as soldering or alloy joining may be used. For example, an Au bump, a Cu bump and a Ni bump coated with solder, and solder balls may be used as the protruding electrodes 204, 206, and 219. The method of mounting the three-layer structure of the semiconductor chips 211a to 211c on the carrier substrate 201 is described in the above-mentioned embodiment. However, a structure in which the semiconductor chips are stacked, which is mounted on the carrier substrate 201, may consist of two, four or more layers.

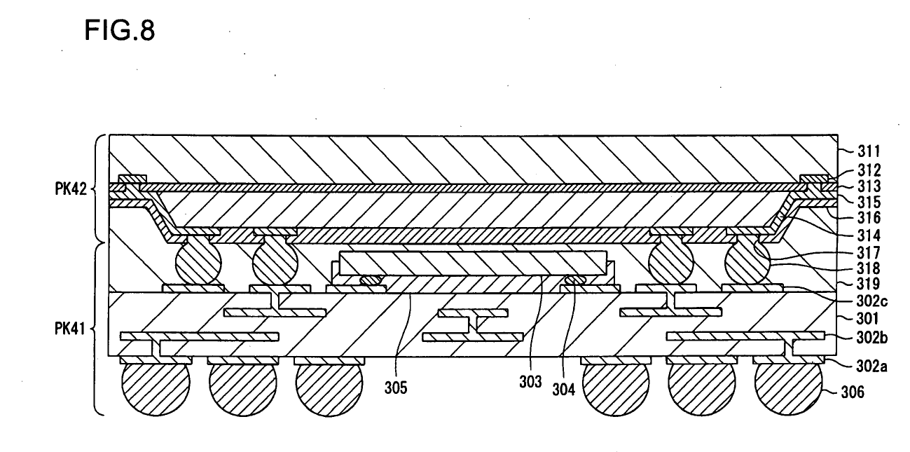

FIG. 8 is a sectional view illustrating the structure of a semiconductor device according to an eighth embodiment of the present invention. According to the eighth embodiment, a W-CSP (a wafer level chip size package) is three-dimensionally mounted on a carrier substrate 301 on which a semiconductor chip 303 is flip-chip mounted.

In FIG. 8, the carrier substrate 301 is provided in a semiconductor package PK41. Lands 302a and 302c are respectively formed on both faces of the carrier substrate 301. Internal wiring lines 302b are formed in the carrier substrate 301. The semiconductor chip 303 is flip-chip mounted on the carrier substrate 301. Protruding electrodes 304 for flip-chip mounting the semiconductor chip 303 are provided on the semiconductor chip 303. The protruding electrodes 304 provided on the semiconductor chip 303 are bonded to the lands 302c via an anisotropic conductive film 305 by ACF bonding. Protruding electrodes 306 for mounting the carrier substrate 301 on a mother substrate are provided on the lands 302a on the reverse face of the carrier substrate 301.

On the other hand, a semiconductor chip 311 is provided in a semiconductor package PK42. Electrode pads 312 are provided on the semiconductor chip 311. An insulating film 313 is provided so as to expose the electrode pads 312. A stress-relieving layer 314 is formed on the semiconductor chip 311 so that the electrode pads 312 are exposed. A re-arrangement wiring line 315 extending on the stress-relieving layer 314 is formed on the electrode pads 312. A solder resist film 316 is formed on the re-arrangement wiring line 315. Apertures 317 for exposing the re-arrangement wiring line 315 on the stress-relieving layer 314 are formed in the solder resist film 316. Protruding electrodes 318 for mounting the semiconductor chip 311 face down on the carrier substrate 301 are provided on the re-arrangement wiring line 315 exposed through the apertures 317 so that the semiconductor chip 311 is held above the semiconductor chip 303.

The protruding electrodes 318 are arranged so as to avoid the region on which the semiconductor chip 303 is mounted, for example, around a peripheral region of the reverse face of the semiconductor chip 311. The protruding electrodes 318 are bonded to the lands 302c provided on the carrier substrate 301. The surface of the semiconductor package PK42 mounted on the carrier substrate 301 is sealed with a sealing resin 319. The semiconductor package PK42 is mounted on the carrier substrate 301.

Therefore, it is possible to stack the W-CSP on the carrier substrate 301 on which the semiconductor chip 303 is flip-chip mounted. Even when the kinds or the sizes of the semiconductor chips 303 and 311 vary, it is possible to three-dimensionally mount the semiconductor chip 311 on the semiconductor chip 303 without interposing a carrier substrate between the semiconductor chip 303 and the semiconductor chip 311 and to reinforce the region for arranging the protruding electrodes 318 with sealing resin 319 for sealing the semiconductor package PK42. As a result, it is possible to reduce warpage of the carrier substrate 301 while suppressing an increase in the height when the semiconductor chips 303 and 311 are stacked and thereby save space when the semiconductor chips 303 and 311 are mounted while suppressing the deterioration of the connection reliability when the semiconductor chips 303 and 311 are three-dimensionally mounted.

When the semiconductor package PK42 is mounted on the carrier substrate 301, the semiconductor package PK42 may be attached to or separated from the semiconductor chip 303. When the semiconductor package PK42 is mounted on the carrier substrate 301, pressure welding such as ACF bonding and NCF bonding may be used. The metal joining such as the soldering and alloy joining may be used. For example, an Au bump, a Cu pump and an Ni bump coated with a solder material, and solder balls may be used as the protruding electrodes 304, 306, and 318. The method of mounting the semiconductor package PK42 on one semiconductor chip 303 flip-chip mounted on the carrier substrate 301 is described in the above-mentioned embodiment. However, the semiconductor package PK42 may be mounted on the plurality of semiconductor chips flip-chip mounted on the carrier substrate 301.

Moreover, the above-mentioned semiconductor devices and electronic devices can be applied to electronic apparatuses such as liquid crystal displays, mobile telephones, portable information terminals, video cameras, digital cameras, and mini disc (MD) players to thereby miniaturize and lighten the electronic apparatuses and to improve the reliability of the electronic apparatuses.

Further, a method of mounting the semiconductor chips or the semiconductor packages is described in the above-mentioned embodiment. However, the present invention is not necessarily limited to this method of mounting semiconductor chips or semiconductor packages. For example, ceramic elements such as surface acoustic wave (SAW) elements, optical elements such as optical modulators and optical switches, and various sensors such as magnetic sensors and biosensors may also be mounted.

What is claimed is:

1. A semiconductor device, comprising:
a first carrier substrate;
a first semiconductor chip mounted on the first carrier substrate;
a second carrier substrate;
a second semiconductor chip mounted on the second carrier substrate;
protruding electrodes for connecting the second carrier substrate to the first carrier substrate so that the second carrier substrate is held above the first semiconductor chip; and
a sealant for sealing the second semiconductor chip so as to include a region in which the protruding electrodes are arranged.

2. The semiconductor device according to claim 1,
wherein the second carrier substrate is fixed to the first carrier substrate so as to be mounted on the first semiconductor chip.

3. The semiconductor device according to claim 1,
wherein the sealant further comprises a molded resin.

4. The semiconductor device according to claim 1,
wherein a position of a sidewall of the sealant coincides with a sidewall of the second carrier substrate.

5. The semiconductor device according to claim 1,
wherein the first semiconductor chip is flip-chip mounted on the first carrier substrate.

6. The semiconductor device according to claim 1,
wherein a plurality of the first semiconductor chips is provided in parallel on the first carrier substrate.

7. The semiconductor device according to claim 6,
wherein the first semiconductor chips are connected to the first carrier substrate by pressure welding.

8. The semiconductor device according to claim 1,
wherein, at the same temperature, an elastic modulus of a semiconductor device including the first carrier substrate and the first semiconductor chip mounted on the first carrier substrate is different from an elastic modulus of a semiconductor device including the second carrier substrate and the second semiconductor chip mounted on the second carrier substrate.

9. The semiconductor device according to claim 1,
wherein the first carrier substrate on which the first semiconductor chip is mounted further comprises a flip-chip-mounted ball grid array, and
wherein the second carrier substrate on which the second semiconductor chip is mounted further comprises at least one of a mold-sealed ball grid array and a chip size package.

10. A semiconductor device, comprising:
a carrier substrate;
a first semiconductor chip mounted on the carrier substrate;
a second semiconductor chip mounted on the carrier substrate;
protruding electrodes for connecting the second semiconductor chip to the carrier substrate so that the second semiconductor chip is held above the first semiconductor chip; and
a sealant for sealing the second semiconductor chip so as to include a region in which the protruding electrodes are arranged.

11. The semiconductor device according to claim 10,
wherein the second semiconductor chip comprises a plurality of stacked semiconductor chips.

12. The semiconductor device according to claim 10,
wherein the second semiconductor chip comprises a plurality of semiconductor chips mounted in parallel on the second carrier substrate.

13. An electronic device, comprising:
a first carrier substrate;
a first electronic part mounted on the first carrier substrate;
a second carrier substrate;
a second electronic part mounted on the second carrier substrate;
protruding electrodes connecting the second carrier substrate to the first carrier substrate so that the second carrier substrate is held above the first electronic part; and
a sealant sealing the second electronic part so as to include a region in which the protruding electrodes are arranged.

14. An electronic apparatus, comprising:
a first carrier substrate;
a first semiconductor chip mounted on the first carrier substrate;
a second carrier substrate;
a second semiconductor chip mounted on the second carrier substrate;
protruding electrodes connecting the second carrier substrate to the first carrier substrate so that the second carrier substrate is held above the first semiconductor chip;
a sealant sealing the second semiconductor chip so as to include a region in which the protruding electrodes are arranged; and
a mother substrate on which the first carrier substrate is mounted.

15. A method of manufacturing a semiconductor device, comprising the steps of:
flip-chip mounting a first semiconductor chip on a first carrier substrate;
mounting a second semiconductor chip on a second carrier substrate in which an arrangement region for arranging protruding electrodes is provided;
sealing the second semiconductor chip with a sealing resin so that the sealing resin is attached to the region for arranging the protruding electrodes; and
connecting the second carrier substrate to the first carrier substrate via the protruding electrodes so that the second carrier substrate is held above the first semiconductor chip.

16. The method of manufacturing a semiconductor device according to claim 15, wherein the step of sealing the second semiconductor chip with the sealing resin comprises the steps of:
integrally molding a plurality of the second semiconductor chips, which are mounted on the second carrier substrate, with the sealing resin; and
cutting the second carrier substrate molded with the sealing resin into pieces so that each piece includes one of the second semiconductor chips.

17. A method of manufacturing an electronic device, comprising the steps of:
mounting a first electronic part on a first carrier substrate;
mounting a second electronic part on a second carrier substrate in which an arrangement region for arranging protruding electrodes is provided;
sealing the second electronic part with a sealing resin so that the sealing resin is attached to the region for arranging the protruding electrodes; and
connecting the second carrier substrate to the first carrier substrate via protruding electrodes so that the second carrier substrate is held above the first electronic part.

18. The semiconductor device according to claim 1,
wherein the second semiconductor chip comprises a plurality of stacked semiconductor chips.

19. The semiconductor device according to claim 1,
wherein the second semiconductor chip comprises a plurality of semiconductor chips mounted in parallel on the second carrier substrate.
